(19) United States
(12) Patent Application Publication
(10) Pub. No.: US 2026/0052702 A1
(43) Pub. Date: Feb. 19, 2026

(54) ELECTRONIC DEVICE AND METHOD FOR FABRICATING THE SAME

(71) Applicant: SK hynix Inc., Gyeonggi-do (KR)

(72) Inventors: Jung Hyeok KWAK, Gyeonggi-do (KR); Tae Yup KIM, Gyeonggi-do (KR); Ku Youl JUNG, Gyeonggi-do (KR); Jin Won JUNG, Gyeonggi-do (KR)

(21) Appl. No.: 19/056,583

(22) Filed: Feb. 18, 2025

(30) Foreign Application Priority Data
Aug. 13, 2024 (KR) 10-2024-0108295

(51) Int. Cl. H10B 61/00; H10N 50/01; H10N 50/10

(52) U.S. Cl. CPC H10B 61/10; H10N 50/01; H10N 50/10

(57) ABSTRACT

A semiconductor device comprising a variable resistance memory layer, wherein the memory layer includes a magnetic tunnel junction structure including a free layer having a changeable magnetization direction, a fixed layer having a fixed magnetization direction, a tunnel barrier layer disposed between the free layer and the fixed layer, and a magnetic oxide layer disposed on a sidewall of the free layer.

### CROSS-REFERENCE TO RELATED APPLICATIONS

The present application claims priority under 35 U.S.C 119(a) to Korean Patent Application No. 10-2024-0108295, filed on Aug. 13, 2024, which is incorporated herein by reference in its entirety.

### BACKGROUND

### 1. Field

Embodiments of the present disclosure relate generally to a semiconductor technology, and more particularly, to a semiconductor device including a magnetic tunnel junction structure, and a method for fabricating the same.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices. Researchers and the industry are studying to develop such semiconductor devices. The semiconductor devices capable of storing data by taking advantage of the characteristic of switching between different resistance states according to the applied voltage or current may include a Resistive Random Access Memory (RRAM), a Phase-change Random Access Memory (PRAM), a Ferroelectric Random Access Memory (FRAM), a Magnetic Random Access Memory (MRAM), an e-fuse and the like.

### SUMMARY

Embodiments of the present disclosure are directed to a semiconductor device including a semiconductor memory capable of improving (delta improvement) data retention of a magnetic tunnel junction structure, and a method for fabricating the semiconductor device.

In accordance with an embodiment of the present disclosure, a semiconductor device includes a variable resistance memory layer, wherein the variable resistance memory layer includes a magnetic tunnel junction structure including a free layer having a changeable magnetization direction, a fixed layer having a fixed magnetization direction, and a tunnel barrier layer disposed between the free layer and the fixed layer, and a magnetic oxide layer disposed on a sidewall of the free layer.

In accordance with another embodiment of the present disclosure, a method for fabricating a semiconductor device includes forming a magnetic tunnel junction structure including a fixed layer, a tunnel barrier layer, and a free layer over a substrate; and forming a magnetic oxide layer on a sidewall of the free layer of the magnetic tunnel junction structure by angled sputtering deposition.

In accordance with another embodiment of the present disclosure, a method for fabricating a semiconductor device includes sequentially forming a lower electrode layer, a magnetic tunnel junction layer including a free layer, and a hard mask layer over a substrate; selectively etching and patterning the magnetic tunnel junction layer by etching the top surface of the magnetic tunnel junction layer and the hard mask layer to produce a patterned magnetic tunnel junction layer; and forming a magnetic oxide layer on a sidewall of the magnetic tunnel junction layer by performing an angled ion-implantation process of implanting a magnetic oxide into the top surface of the patterned magnetic tunnel junction layer.

These and other features and advantages of the embodiments of the present disclosure will become better understood by those with ordinary skill in the art from the following example figures and illustrated embodiments.

### BRIEF DESCRIPTION OF THE DRAWINGS

FIGS. 1 to 6 are simplified cross-sectional views illustrating a semiconductor device and a fabrication method thereof in accordance with an embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The illustrated embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure. The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Throughout the disclosure, the term “approximately” should be interpreted as indicating a range of ±5%.

A magnetic tunnel junction (MTJ) structure may include a free layer having a changeable magnetization direction, a fixed layer having a fixed magnetization direction, and a tunnel barrier layer disposed between the free layer and the fixed layer. In a variable resistance element, the magnetization direction of the free layer may be changed to be parallel to or anti-parallel to the magnetization direction of the fixed layer according to an applied voltage or current, and accordingly, the magnetic tunnel junction structure may switch between a low resistance state and a high resistance state. In embodiment of the present disclosure described below, an improved magnetic tunnel junction structure is provided. The inventive magnetic tunnel structure is capable of improving at least one characteristic of the magnetic tunnel junction structure.

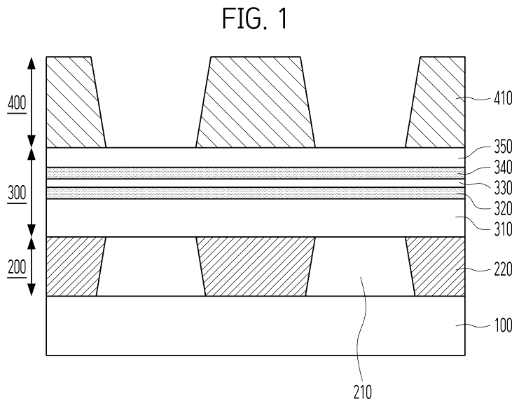

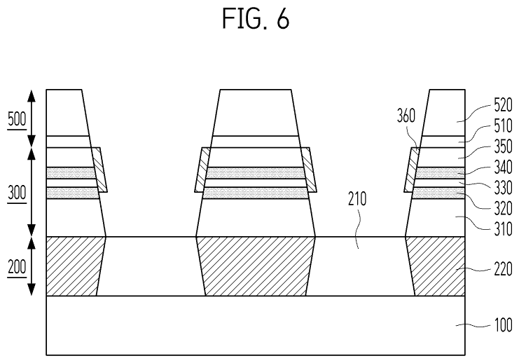

FIGS. 1 to 6 are simplified cross-sectional views illustrating a semiconductor device and a method for fabricating the same in accordance with an embodiment of the present disclosure. FIG. 6 illustrates a semiconductor device in accordance with the embodiment of the present disclosure. FIGS. 1 to 5 illustrate intermediate processes for fabricating the semiconductor device shown in FIG. 6 according to an embodiment of the present disclosure.

First, a method for fabricating the semiconductor device may be described.

Referring to FIG. 1, a substrate 100 is provided, and an inter-layer dielectric layer 210 is formed over the substrate 100. The inter-layer dielectric layer 210 may be a single layer or a multi-layer. For example, the lower inter-layer dielectric layer 210 may include silicon oxide, silicon nitride, silicon oxynitride, and/or a low-k material. A low-k material refers to a material having a dielectric constant (k) of approximately 4 or less. As the value becomes smaller, the electrical insulating characteristics may be improved, and the parasitic capacitance between elements may be reduced. The low-k materials may include silicon oxide, organic siloxane, silicon carbide, organic-based materials including benzene rings or fluorine, and porous materials, however, the technical concepts and scope of the present disclosure are not limited thereto.

Over the substrate 100 where the inter-layer dielectric layer 210 is formed, a lower electrode layer 200 penetrating the inter-layer dielectric layer 210, a magnetic tunnel junction layer 300 including a free layer 330, and a hard mask layer 400 may be sequentially formed. The lower electrode layer 200, the magnetic tunnel junction layer 300, and the hard mask layer 400 may be formed by a sputtering method, a Physical Vapor Deposition (PVD) method, a Chemical Vapor Deposition (CVD) method, or a combination thereof, however, the technical concepts and scope of the present disclosure are not limited thereto.

First, the lower electrode layer (not shown) may be patterned to form a lower electrode 220. For example, the lower electrode 220 may be formed by forming a mask pattern (not shown) over the lower electrode layer and etching the lower electrode layer with the mask pattern used as an etching mask. The lower electrode layer may be etched by a physical etching process, such as an Ion Beam Etching (IBE) process, using ions such as argon (Ar) ions, krypton (Kr) ions and the like, or a chemical etching process, such as a Reactive Ion Etching (RIE) process. The lower electrode 220 may include at least one of a conductive metal nitride (for example, titanium nitride or tantalum nitride) and a rare earth metal (for example, ruthenium, platinum, and the like). IBE is a physical etching process that may perform an etching process with very high directionality by using a high-energy ion beam. Therefore, IBE is advantageous when a vertical profile is required. Since RIE is a method of performing an etching process by combining a chemical reaction and a physical impact, the etching speed of RIE is generally faster than the etching speed of IBE, which leads to increased productivity. RIE may be able to perform a selective etching process between a material to be etched and a protective layer or a photoresist to selectively remove only a target layer.

The magnetic tunnel junction layer 300 may include a fixed layer 310 having a fixed magnetization direction, a tunnel barrier layer 320 and a free layer 330 having a changeable magnetization direction. The tunnel barrier layer 320 is disposed between the free layer 330 and the fixed layer 310. The fixed layer 310, the tunnel barrier layer 320, and the free layer 330 are sequentially stacked over the lower electrode layer 200. The magnetization direction of the free layer 330 may be changed by a magnetic field that is formed between the lower electrode 220 and an upper electrode 520. The upper electrode 520 is shown in FIG. 6. The fixed layer 310 and the free layer 330 may include a material having an interface perpendicular magnetic anisotropy. The interface perpendicular magnetic anisotropy refers to a phenomenon that a magnetic layer having intrinsic horizontal magnetization characteristics comes to have a vertical magnetization direction due to the influence from the interface with another layer which is adjacent to the magnetic layer. Here, the intrinsic horizontal magnetization characteristic refers to the characteristics that the magnetic layer has a magnetization direction which is parallel to the widest surface of the magnetic layer in the absence of an external factor. For example, when a magnetic layer having intrinsic horizontal magnetization characteristics is formed over a substrate and there are no external factors, the magnetization direction of the magnetic layer may be substantially parallel to the top surface of the substrate.

In this case, each of the fixed layer 310 and the free layer 330 may include at least one of cobalt (Co), iron (Fe), and nickel (Ni). Also, each of the fixed layer 310 and the free layer 330 may further include at least one of non-magnetic materials including boron (B), zinc (Zn), aluminum (Al), titanium (Ti), ruthenium (Ru), tantalum (Ta), silicon (Si), silver (Ag), gold (Au), platinum (Pt), palladium (Pd), iridium (Ir), carbon (C), and nitrogen (N). For example, each of the fixed layer 310 and the free layer 330 may include CoFe or NiFe, and may further include boron (B). Also, to lower the saturation magnetization amounts of the fixed layer 310 and the free layer 330, each of the fixed layer 310 and the free layer 330 may further include at least one of titanium (Ti), aluminum (Al), silicon (Si), magnesium (Mg), tantalum (Ta), and silicon (Si). However, the materials of the fixed layer 310 and the free layer 330 may not be limited to these. The fixed layer 310 may also be called a reference layer RL or a shift cancellation layer (SCL), and the fixed layer 310 may have a multi-layer structure. The free layer 330 may also be called a storage layer SL.

The tunnel barrier layer 320 may include at least one among an oxide of magnesium (Mg), an oxide of titanium (Ti), an oxide of aluminum (Al), an oxide of magnesium-zinc (MgZn), an oxide of magnesium-boron (MgB), a nitride of titanium (Ti), and a nitride of vanadium (V). For example, the tunnel barrier layer 320 may be a single layer of magnesium oxide (MgO). Different from this, the tunnel barrier layer 320 may include a plurality of layers.

Subsequently, an oxide layer 340 may be deposited over the free layer 330. The oxide layer 340 may serve as a capping layer. In this case, the oxide layer 340 may be typically formed of the same material as that of the tunnel barrier layer 320, however, the technical concepts and scope of the present disclosure are not necessarily limited thereto and the oxide layer 340 may be formed of an oxide material. For example, the oxide layer 340 may include at least one oxide material selected from the group including HfOₓ, NbOₓ, TaOₓ, and WOₓ. For example, the oxide layer 340 may include a metal oxide selected from the group including RuO, MgO, VO, WO, NbO, TaO, HfO, MoO, GdO, AlO, IrO, and combinations thereof.

A capping layer 350 may be formed over the oxide layer 340. The capping layer 350 may induce the free layer 330 to have a magnetization direction that is perpendicular to the substrate 100. Accordingly, the free layer 330 may have an interface perpendicular magnetic anisotropy. Also, the capping layer 350 may suppress a phenomenon in which a metal constituting the free layer 330 is lost by being diffused to the outside and may prevent oxidation of the free layer 330. The capping layer 350 may be a multi-layer structure including a metal element, such as ruthenium (Ru), tantalum (Ta), hafnium (Hf), platinum (Pt), molybdenum (Mo), and tungsten (W) and the like, and a non-metal element, such as boron (B).

The electrical resistance of the magnetic tunnel junction layer 300 may depend on the magnetization directions of the fixed layer 310 and the free layer 330. For example, the electrical resistance of the magnetic tunnel junction layer 300 may be much larger when the magnetization directions of the fixed layer 310 and the free layer 330 are anti-parallel to each other than when the magnetization directions of the fixed layer 310 and the free layer 330 are parallel to each other. As a result, the electrical resistance of the magnetic tunnel junction layer 300 may be controlled by changing the magnetization direction of the free layer 330, which may be utilized as a data storage principle in a semiconductor device according to the embodiment of the present disclosure.

A pillar-shaped hard mask layer 400 may be deposited on the top surface of the capping layer 350, and the pillar-shaped hard mask layer 400 may be formed of a dielectric material, such as silicon nitride or silicon oxynitride. The hard mask layer 400 may include at least one of, for example, carbon (C), silicon (Si), copper (Cu), tungsten (W), titanium (Ti), tantalum (Ta) and aluminum (Al), nitrides, oxides, and borides thereof, and metal nitrides (e.g., titanium nitride and tantalum nitride) thereof. The hard mask layer 400 may protect the underlying layers under the process conditions of a subsequent process. By forming the pillar-shaped hard mask layer 400, the magnetic tunnel junction layer 300 may be selectively etched to form a patterned pillar-shaped magnetic tunnel junction layer 300, as described below.

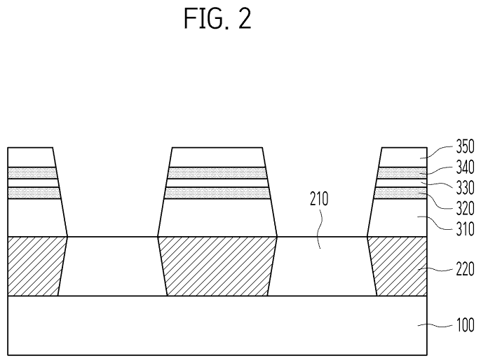

Referring to FIG. 2, the magnetic tunnel junction layer 300 may be selectively etched and patterned by etching the top surface of the process structure shown in FIG. 1. This etching process may be performed by a physical etching process, such as the ion beam etching (IBE) process, or a chemical etching process, such as the reactive ion etching (RIE) process.

The hard mask layer 400 may have an etching selectivity with respect to the magnetic tunnel junction layer 300. The ion beam or the reactive ion may include an inert ion. For example, the hard mask 410 may be etched by the ion beam etching (IBE) process or the reactive ion etching (RIE) process, and the top surface of the inter-layer dielectric layer 210 of the lower electrode layer 200 may be recessed on both sides of the hard mask 410. The above etching process may be performed until the top surface of the inter-layer dielectric layer 210 is exposed.

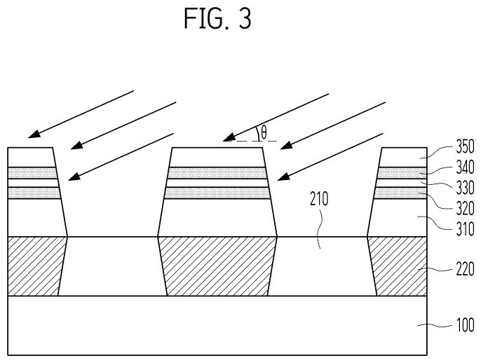

Referring to FIG. 3, a magnetic oxide, particularly a ferrimagnetic oxide, may be deposited on the top surface of the patterned pillar-shaped magnetic tunnel junction layer 300 by an angled sputtering process to form a magnetic oxide layer, particularly a ferrimagnetic oxide layer 360, over the sidewall of the magnetic tunnel junction layer 300.

A ferrimagnetic oxide may be deposited on a portion of the patterned pillar-shaped magnetic tunnel junction layer 300 by an angled sputtering deposition process. The ferrimagnetic oxide may be deposited by the angled sputtering deposition process, so that the ferrimagnetic oxide layer 360 may be formed to have a uniform thickness on the sidewall of the free layer 330 of the magnetic tunnel junction structure. The sputtering deposition process is particularly effective in forming a uniform and high-density thin layer, and allows high precision and control. The sputtering deposition process is also particularly effective in enabling the formation of a multi-layer structure. In the sputtering deposition process, the direction that a deposition material is implanted may be controlled. Specifically, in the sputtering deposition process the deposition material may be supplied obliquely with respect to a line perpendicular to the surface of the substrate. The angle between the direction that the deposition material is supplied and the line perpendicular to the surface of the substrate may be defined as a deposition angle θ. Magnetron sputtering equipment may be adopted as the equipment for performing the angled sputtering deposition process.

The deposition angle θ may be determined such that the ferrimagnetic oxide layer 360 may cover a portion of the magnetic tunnel junction layer 300, preferably the free layer 330. According to one embodiment of the present disclosure, the angled sputtering deposition process may utilize a deposition angle having a vertical inclination of approximately 50 to 80 degrees with respect to a line perpendicular to the surface of the substrate. During the angled sputtering deposition process, the deposition angle and the number of times that the deposition is performed may be controlled according to the type and shape of the top surface of the patterned magnetic tunnel junction layer 300. The ferrimagnetic oxide layer may include at least one selected from the group including Fe₃O₄, CoFe₂O₄, ZnFe₂O₄, NiFe₂O₄, ReFe₂O₄, PbFe₁₂O₁₉, BaFe₁₂O₁₉, Dy₃Fe₅O₁₂, Y₃Fe₅O₁₂, MnFe₂O₄, and MgFe₂O₄, however, the technical concepts and scope of the present disclosure are not limited thereto. In general, a ferrimagnetic material may have the characteristics that saturation magnetization is increased as the temperature is increased. As the saturation magnetization of the ferrimagnetic material is increased, the demagnetization field may be increased and the anisotropy field may be decreased.

The angled sputtering deposition process may deposit a magnetic oxide, particularly a ferrimagnetic oxide, on the sidewall of the magnetic tunnel junction layer 300, preferably the free layer 330, by using a radio frequency (RF)-sputtering method that enters at a low angle. Here, the deposition angle may be adjusted so that the ferrimagnetic oxide is not deposited onto the magnetic tunnel junction layer 300 below the tunnel barrier layer 320. However, the ferrimagnetic oxide may also be deposited on the surfaces of the oxide layer 330 and the hard mask over the free layer 330.

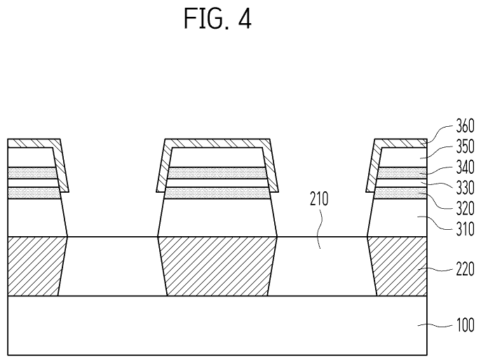

Referring to FIG. 4, a portion of the deposited ferrimagnetic oxide layer 360 on the sidewall of the free layer 330 may have the same magnetization direction as that of the free layer due to the influence of a stray field of the free layer. This may serve as an additional volume of the free layer. In general, the effect (delta improvement) of improving the data retention of the magnetic tunnel junction layer 300 may be proportional to the perpendicular magnetic anisotropy of the free layer 330 and the volume of the free layer 330. Therefore, when the perpendicular magnetic anisotropy of the free layer 330 is increased, the data retention of the magnetic tunnel junction layer 300 may be improved, but even without any improvement in the perpendicular magnetic anisotropy as shown in the embodiment of the present disclosure, the data retention may be improved due to the increase in the volume of the free layer 330.

The bottom surface of the ferrimagnetic oxide layer 360 may be disposed at a height equal to or higher than the bottom surface of the tunnel barrier layer 320. The thickness of the formed ferrimagnetic oxide layer 360 may be in the range of approximately 0.1 nm to 5.0 nm. When the thickness of the ferrimagnetic oxide layer 360 is less than approximately 0.1 nm, the effect (delta improvement) of improving the data retention of the magnetic tunnel junction layer 300 may be insignificant, which is not desirable. When the thickness of the ferrimagnetic oxide layer 360 is more than approximately 5.0 nm, the magnetic layer may be formed to be excessively thick, which may cause inter-cell bridge or a stray field, which is not desirable.

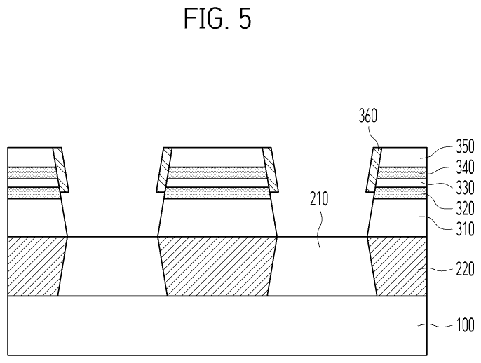

Referring to FIG. 5, the ferrimagnetic oxide layer 360 formed over the oxide layer 340 may be etched to form an intermediate electrode layer 510, which will be described below. This etching process may include a dry etching process, such as the ion beam etching (IBE) process. Here, the IBE process may be performed multiple times in a diagonal direction which is not perpendicular to the top surface of the substrate 100, and the IBE process may be performed by using an etching gas including a fluorine-containing gas and an ammonia (NH₃) gas and oxygen gas for suppressing the consumption of the oxide layer 340 as reaction gases.

The dry etching process may be performed multiple times. For example, the dry etching process may be performed by performing the IBE process three times, and each of the IBE processes may be performed at an angle of approximately 5° to 45° with respect to the top surface of the substrate 100. Also, the dry etching process may be performed as the reactive ion etching (RIE) process. The ferrimagnetic oxide layer 360 that is formed on the sidewall of the free layer 330 through this etching process may not be etched, but the ferrimagnetic oxide layer 360 formed over the oxide layer 340 may be selectively etched.

Referring to FIG. 6, an intermediate electrode layer 510 may be formed over the ferrimagnetic oxide layer 360. The intermediate electrode layer 510 may function to electrically connect the magnetic tunnel junction layer 300 and the upper electrode layer 500 to each other while physically separating them from each other. The intermediate electrode layer 510 may include a metal material having a lower specific gravity than that of the upper electrode layer which is formed in a subsequent process. For example, the intermediate electrode layer 510 may include diverse conductive materials, for example, a metal such as platinum (Pt), tungsten (W), aluminum (Al), copper (Cu), tantalum (Ta) and the like, a metal nitride such as titanium nitride (TiN), tantalum nitride (TaN) and the like, or a combination thereof. The intermediate electrode layer 510 may also include a carbon electrode. The intermediate electrode layer 510 and the upper electrode layer which is formed in the subsequent process may be formed by using a chemical vapor deposition (CVD) method, a metal organic chemical vapor deposition (MOCVD) method, or a plasma enhanced chemical vapor deposition (PECVD) method.

Subsequently, the upper electrode layer (not shown) may be patterned to form an upper electrode 520 over the magnetic tunnel junction layer 300. For example, the upper electrode 520 may be formed by forming a mask pattern (not shown) over the upper electrode layer and etching the upper electrode layer with the mask pattern used as an etching mask. The upper electrode layer may be etched by a physical etching process, such as the ion beam etching (IBE) process, using ions such as argon (Ar) ions, krypton (Kr) ions and the like, or a chemical etching process, such as the reactive ion etching (RIE) process. The upper electrode 520 may include a conductive material whose resistance is lower than that of the intermediate electrode layer 510. For example, the upper electrode 520 may include at least one of a conductive metal nitride (for example, titanium nitride or tantalum nitride) and a rare earth metal (for example, ruthenium, platinum, and the like).

As a result of the process described above, the semiconductor device illustrated in FIG. 6 may be fabricated.

Referring back to FIG. 6, the semiconductor device in accordance with an embodiment of the present disclosure may include the lower electrode layer 200, the magnetic tunnel junction layer 300, and the upper electrode layer 500 that are formed over the substrate 100. The lower electrode layer 200 may include a lower electrode 220 that is formed to penetrate an inter-layer dielectric layer 210, and the magnetic tunnel junction layer 300 may include a fixed layer 310 having a fixed magnetization direction, a tunnel barrier layer 320 disposed between the free layer 330 and the fixed layer 310, an oxide layer 340 covering the free layer 330, and a capping layer 350 formed over the oxide layer 340. The upper electrode layer 500 may include an intermediate electrode layer 510 and an upper electrode 520. The oxide layer 340 may include a metal oxide selected from the group including RuO, MgO, VO, WO, TaO, HfO, MoO, and combinations thereof. The ferrimagnetic oxide layer 360 may be formed on the sidewall of the magnetic tunnel junction structure, preferably on the sidewall of the free layer 330.

The bottom surface of the ferrimagnetic oxide layer 360 may be disposed at a height which is equal to or higher than the bottom surface of the tunnel barrier layer 320. The thickness of the ferrimagnetic oxide layer 360 may be in the range of approximately 0.1 nm to 5.0 nm. The ferrimagnetic oxide layer may include at least one selected from the group including Fe₃O₄, CoFe₂O₄, ZnFe₂O₄, NiFe₂O₄, ReFe₂O₄, PbFe₁₂O₁₉, BaFe₁₂O₁₉, Dy₃Fe₅O₁₂, Y₃Fe₅O₁₂, MnFe₂O₄, and MgFe₂O₄, however, the technical concepts and scope of the present disclosure are not limited thereto.

According to the semiconductor device and the fabrication method thereof described above, the ferrimagnetic oxide layer 360 formed on the sidewall of the free layer 330 may serve as an additional volume of the free layer 330 to obtain the effect of improving the data retention even without any improvement in the perpendicular magnetic anisotropy.

According to the embodiment of the present disclosure, the data retention (delta) of a magnetic tunnel junction structure may be improved by depositing a magnetic oxide, particularly a ferrimagnetic oxide, on the sidewall of a magnetic tunnel junction structure.

While the embodiments of the present disclosure has been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device, comprising:
a variable resistance memory layer,
wherein the memory layer includes a magnetic tunnel junction structure including
a free layer having a changeable magnetization direction,
a fixed layer having a fixed magnetization direction, and
a tunnel barrier layer disposed between the free layer and the fixed layer, and
a magnetic oxide layer disposed on a sidewall of the free layer.

2. The semiconductor device of claim 1, wherein the magnetic oxide layer is a ferrimagnetic oxide layer. θ

3. The semiconductor device of claim 1, wherein the magnetic oxide layer is formed only on a bottom surface of the tunnel barrier layer or higher.

4. The semiconductor device of claim 1, wherein a thickness of the magnetic oxide layer is in a range of approximately 0.1 nm to 5.0 nm.

5. The semiconductor device of claim 2, wherein the ferrimagnetic oxide layer includes at least one selected from a group including Fe₃O₄, CoFe₂O₄, ZnFe₂O₄, NiFe₂O₄, ReFe₂O₄, PbFe₁₂O₁₉, BaFe₁₂O₁₉, Dy₃Fe₅O₁₂, Y₃Fe₅O₁₂, MnFe₂O₄, and MgFe₂O₄.

6. The semiconductor device of claim 1, wherein the magnetic tunnel junction structure further includes an oxide layer suitable for covering the free layer.

7. The semiconductor device of claim 6, wherein the oxide layer includes a metal oxide selected from a group including RuO, MgO, VO, WO, NbO, TaO, HfO, MoO, GdO, AlO, IrO, and combinations thereof.

8. The semiconductor device of claim 1, further comprising
a lower electrode and an upper electrode disposed in lower and upper portions of the magnetic tunnel junction structure, respectively.

9. The semiconductor device of claim 1, wherein the magnetic oxide layer has the same magnetization direction as a magnetization direction of the free layer.

10. A method for fabricating a semiconductor device, the method comprising:
forming a magnetic tunnel junction structure including a fixed layer, a tunnel barrier layer, and a free layer over a substrate; and
forming a magnetic oxide layer on a sidewall of the free layer of the magnetic tunnel junction structure by an angled sputtering deposition process.

11. The method of claim 10, wherein the magnetic oxide layer is a ferrimagnetic oxide layer.

12. The method of claim 10, wherein the magnetic oxide layer is formed on the sidewall of the magnetic tunnel junction structure only above a bottom surface of the tunnel barrier layer.

13. The method of claim 10, wherein a thickness of the magnetic oxide layer is in a range of approximately 0.1 nm to 5.0 nm.

14. The method of claim 11, wherein the ferrimagnetic oxide layer includes at least one selected from a group consisting of Fe₃O₄, CoFe₂O₄, ZnFe₂O₄, NiFe₂O₄, ReFe₂O₄, PbFe₁₂O₁₉, BaFe₁₂O₁₉, Dy₃Fe₅O₁₂, Y₃Fe₅O₁₂, MnFe₂O₄, and MgFe₂O₄.

15. The method of claim 10, wherein the angled sputtering deposition process is performed by a radio frequency (RF)-sputtering process.

16. The method of claim 10, wherein the angled sputtering deposition process is performed at a deposition angle of approximately 50 to 80 degrees with respect to a line perpendicular to a surface of the substrate.

17. The method of claim 10, wherein forming the magnetic tunnel junction layer including the free layer includes
depositing an oxide layer over the free layer.

18. The method of claim 17, wherein the oxide layer includes
a metal oxide selected from a group including RuO, MgO, VO, WO, NbO, TaO, HfO, MoO, GdO, AlO, IrO, and combinations thereof.

19. The method of claim 10, further comprising:
forming a lower electrode below the magnetic tunnel junction layer; and
forming an upper electrode over the magnetic tunnel junction layer.

20. The method of claim 10, wherein the hard mask layer includes
carbon (C), silicon (Si), copper (Cu), tungsten (W), titanium (Ti), tantalum (Ta), aluminum (Al), or a nitride or oxide thereof.
